(19) United States
(12) Patent Application Publication
(10) Pub. No.: US 2019/0093955 A1
(43) Pub. Date: Mar. 28, 2019

(54) DUAL-LOOP LIQUID COOLING SYSTEM

(71) Applicant: AURAS Technology Co., Ltd., New Taipei City (TW)

(72) Inventors: AN-CHIH WU, New Taipei City (TW); CHIH-WEI CHEN, New Taipei City (TW); YEN-HUNG LIN, New Taipei City (TW)

(21) Appl. No.: 15/788,066

(22) Filed: Oct. 19, 2017

(30) Foreign Application Priority Data
Sep. 28, 2017 (TW) 106133426

(51) Int. Cl. F28D 7/00; F28F 1/32; F28F 9/22; H05K 7/20

(52) U.S. Cl. CPC F28D 7/0066; H05K 7/20263; F28F 9/22; F28F 1/32

(57) ABSTRACT

A dual-loop liquid cooling system is provided. A working liquid flows in the dual-loop liquid cooling system to facilitate heat dissipation. The dual-loop liquid cooling system includes a main liquid cooling head, a first loop assembly and a second loop assembly. The first loop assembly is connected with a first inlet and a first outlet of the main liquid cooling head. A first cooling loop system is defined by the first loop assembly and the main liquid cooling head collaboratively. The second loop assembly is connected with a second inlet and a second outlet of the main liquid cooling head. A second cooling loop system is defined by the second loop assembly and the main liquid cooling head collaboratively. Consequently, the cooling efficiency of removing the heat from the main liquid cooling head is enhanced.

### FIELD OF THE INVENTION

The present invention relates to a liquid cooling system, and more particularly to a dual-loop liquid cooling system.

### BACKGROUND OF THE INVENTION

With increasing development of computers and various electronic devices, people in the modern societies are used to using the computers and the electronic devices for a long time. During operations of the computers and the electronic devices, a great deal of heat is generated. If the heat cannot be effectively dissipated away, some drawbacks occur. For facilitating heat dissipation, a liquid cooling system has been disclosed.

Conventionally, the liquid cooling system comprises a liquid cooling head, a liquid pump and a liquid cooling radiator. For increasing the cooling efficiency of the conventional liquid cooling system, the size of the liquid cooling radiator must be large enough to achieve more heat dissipating area. However, as the trends of designing the commercial electronic device is toward miniaturization, the volume and the installation space of the liquid cooling radiator are limited. In other words, the conventional liquid cooling system needs to be further improved.

### SUMMARY OF THE INVENTION

For solving the drawbacks of the conventional technologies, the present invention provides a dual-loop liquid cooling system. A main liquid cooling head is a core of the dual-loop liquid cooling system. A working liquid flows in a first loop assembly and a second loop assembly. The first loop assembly and the second loop assembly are connected with the main liquid cooling head in parallel. Consequently, the heat dissipating efficiency of the liquid cooling system is enhanced.

In accordance with an aspect of the present invention, there is provided a dual-loop liquid cooling system for allowing a working liquid to flow therein to facilitate heat dissipation. The dual-loop liquid cooling system includes a main liquid cooling head, a first loop assembly and a second loop assembly. The main liquid cooling head includes a common chamber, a first inlet, a first outlet, a second inlet and a second outlet. The common chamber is in fluid communication with the first inlet, the first outlet, the second inlet and the second outlet. The first loop assembly includes a first pipe group, a first liquid pump and a first heat dissipation device. The two ends of the first pipe group are respectively connected with the first inlet and the first outlet of the main liquid cooling head. The first pipe group is in fluid communication with the first liquid pump. The second loop assembly includes a second pipe group, a second liquid pump and a second heat dissipation device. The two ends of the second pipe group are respectively connected with the second inlet and the second outlet of the main liquid cooling head. The second pipe group is in fluid communication with the second liquid pump. A first portion of the working liquid in the first loop assembly is driven by the first liquid pump and introduced into the common chamber through the first inlet of the main liquid cooling head. A second portion of the working liquid in the second loop assembly is driven by the second liquid pump and introduced into the common chamber through the second inlet of the main liquid cooling head. After the first portion of the working liquid and the second portion of the working liquid are collected in the common chamber, the working liquid is returned back to the first loop assembly and the second loop assembly through the first outlet and the second outlet of the main liquid cooling head, respectively.

In an embodiment, the first loop assembly further includes a first auxiliary liquid cooling head for receiving the first portion of the working liquid from the main liquid cooling head and/or the second loop assembly further comprises a second auxiliary liquid cooling head for receiving the second portion of the working liquid from the main liquid cooling head. The first portion of the working liquid is sequentially transmitted through the first auxiliary liquid cooling head, the first heat dissipation device and the first liquid pump and returned back to the main liquid cooling head. The second portion of the working liquid is sequentially transmitted through the second auxiliary liquid cooling head, the second heat dissipation device and the second liquid pump and returned back to the main liquid cooling head.

In an embodiment, the main liquid cooling head has a thermal contact area for absorbing heat from an external low-watt heat source, and the first auxiliary liquid cooling head and the second auxiliary liquid cooling head have respective thermal contact areas for absorbing heat from two external high-watt heat sources. The thermal contact area of the main liquid cooling head is smaller than the thermal contact area of the first auxiliary liquid cooling head and the thermal contact area of the second auxiliary liquid cooling head.

In an embodiment, the first pipe group includes four first pipes and/or the second pipe group includes four second pipes. The four first pipes are respectively arranged between the main liquid cooling head and the first auxiliary liquid cooling head, between the first auxiliary liquid cooling head and the first heat dissipation device, between the first heat dissipation device and the first liquid pump and between the first liquid pump and the main liquid cooling head. The second pipes are respectively arranged between the main liquid cooling head and the second auxiliary liquid cooling head, between the second auxiliary liquid cooling head and the second heat dissipation device, between the second heat dissipation device and the second liquid pump and between the second liquid pump and the main liquid cooling head.

In an embodiment, the first heat dissipation device and the second heat dissipation device are liquid cooling radiators. Each of the liquid cooling radiators includes a liquid cooling channel, an entrance, an exit and plural fins. The liquid cooling channel, the entrance and the exit are in communication with each other. The plural fins are in thermal contact with the liquid cooling channel.

In an embodiment, after the first portion of the working liquid is introduced into the corresponding liquid cooling channel through the corresponding entrance to perform heat exchange, the first portion of the working liquid is outputted from the corresponding liquid cooling channel to the first liquid pump through the corresponding exit. Moreover, after the second portion of the working liquid is introduced into the corresponding liquid cooling channel through the corresponding entrance to perform heat exchange, the second portion of the working liquid is outputted from the corresponding liquid cooling channel to the second liquid pump through the corresponding exit.

From the above descriptions, the present invention provides a dual-loop liquid cooling system. The dual-loop liquid cooling system includes two loop assemblies. The two loop assemblies are collaboratively connected with a main liquid cooling head in order to increase the efficiency of removing the heat from the main liquid cooling head. Since the dual-loop liquid cooling system includes the two loop assemblies, the volume of the single heat dissipation device can be reduced. Under this circumstance, the installation space is saved. Moreover, each loop assembly can remove heat from the main liquid cooling head and the auxiliary liquid cooling head sequentially. Consequently, the space utilization is enhanced.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic top view illustrating a dual-loop liquid cooling system according to a first embodiment of the present invention;

FIG. 2 is a schematic cross-sectional view illustrating the first heat dissipation device of the dual-loop liquid cooling system according to the first embodiment of the present invention;

FIG. 3 is a schematic top view illustrating a dual-loop liquid cooling system according to a second embodiment of the present invention;

FIG. 4 is a schematic top view illustrating a dual-loop liquid cooling system according to a third embodiment of the present invention; and

FIG. 5 is a schematic top view illustrating a dual-loop liquid cooling system according to a fourth embodiment of the present invention.

### DETAILED DESCRIPTION OF THE PREFERRED EMBODIMENT

In this context, the term “liquid cooling system” is a system using a working liquid to flow through plural devices to remove the waste heat from an electronic device and reduce the temperature of the electronic device.

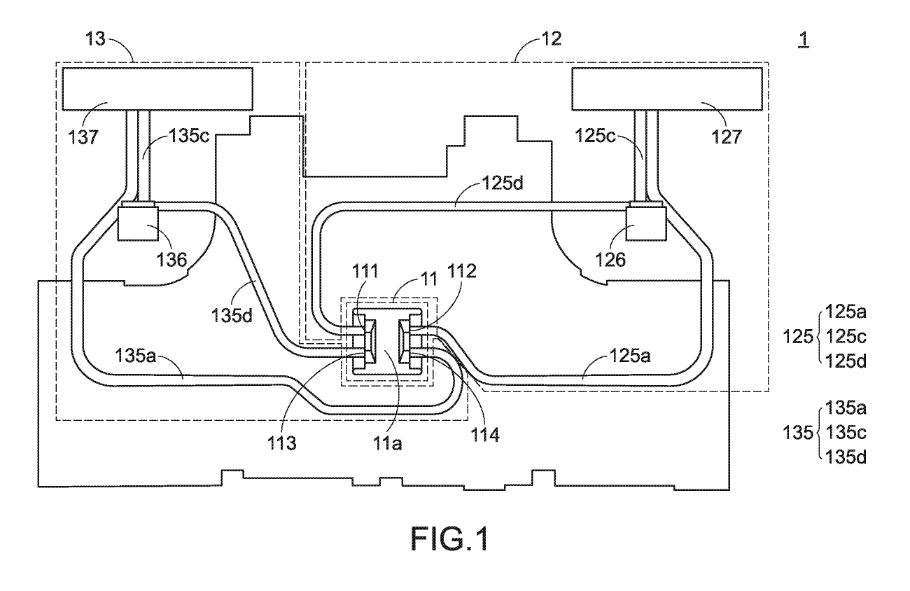

FIG. 1 is a schematic top view illustrating a dual-loop liquid cooling system according to a first embodiment of the present invention. As shown in FIG. 1, the dual-loop liquid cooling system 1 comprises a main liquid cooling head 11, a first loop assembly 12 and a second loop assembly 13. The first loop assembly 12 and the second loop assembly 13 are individually in fluid communication with the main liquid cooling head 11 to dissipate the heat from the main liquid cooling head 11. A first cooling loop system is defined by the first loop assembly 12 and the main liquid cooling head 11 collaboratively. The first cooling loop system is located at a right side of the dual-loop liquid cooling system 1. A second cooling loop system is defined by the second loop assembly 13 and the main liquid cooling head 11 collaboratively. The second cooling loop system is located at a left side of the dual-loop liquid cooling system 1.

The main liquid cooling head 11 comprises a casing. Moreover, the main liquid cooling head 11 comprises a common chamber 11a, a first inlet 111, a first outlet 112, a second inlet 113 and a second outlet 114. The common chamber 11a is disposed within the casing. The common chamber 11a, the first inlet 111, the first outlet 112, the second inlet 113 and the second outlet 114 are located at a periphery region of the casing. That is, the common chamber 11a is in fluid communication with the first inlet 111, the first outlet 112, the second inlet 113 and the second outlet 114.

The first loop assembly 12 comprises a first pipe group 125, a first liquid pump 126 and a first heat dissipation device 127. The first pipe group 125 is in fluid communication with the first liquid pump 126. The first pipe group 125 comprises plural first pipes, which will be described later. The head end and the tail end of the first pipe group 125 are connected with the first inlet 111 and the first outlet 112, respectively. Consequently, the first cooling loop system is defined by the first loop assembly 12 and the main liquid cooling head 11 collaboratively. The working liquid circularly flows in the first cooling loop system to remove the heat from the main liquid cooling head 11. Similarly, the second loop assembly 13 comprises a second pipe group 135, a second liquid pump 136 and a second heat dissipation device 137. The second pipe group 135 is in fluid communication with the second liquid pump 136. The second pipe group 135 comprises plural second pipes, which will be described later. The head end and the tail end of the second pipe group 135 are connected with the second inlet 113 and the second outlet 114, respectively. Consequently, the second cooling loop system is defined by the second loop assembly 13 and the main liquid cooling head 11 collaboratively. The working liquid circularly flows in the second cooling loop system to remove the heat from the main liquid cooling head 11.

In accordance with a feature of the present invention, a first portion of the working liquid in the first loop assembly 12 is driven by the first liquid pump 126 and introduced into the common chamber 11a through the first inlet 111 of the main liquid cooling head 11, and a second portion of the working liquid in the second loop assembly 13 is driven by the second liquid pump 136 and introduced into the common chamber 11 a through the second inlet 113 of the main liquid cooling head 11. The first portion of the working liquid in the first loop assembly 12 and the second portion of the working liquid in the second loop assembly 13 are collected and mixed in the common chamber 11a. After the first portion of the working liquid and the second portion of the working liquid are mixed in the common chamber 11a, the working liquid is returned back to the first loop assembly 12 and the second loop assembly 13 through the first outlet 112 and the second outlet 114 of the main liquid cooling head 11, respectively. Consequently, the uses of the two loop assemblies 12 and 13 can increase the efficiency of removing the heat from the main liquid cooling head 11. Generally, the inner space of the electronic device for installing the liquid cooling system is not large enough. In case that plural loop assemblies (or heat dissipation devices) with smaller volume are used in the liquid cooling system of the present invention, the liquid cooling system can be installed more easily when compared with the liquid cooling system with a large-volume loop assembly (or heat dissipation device).

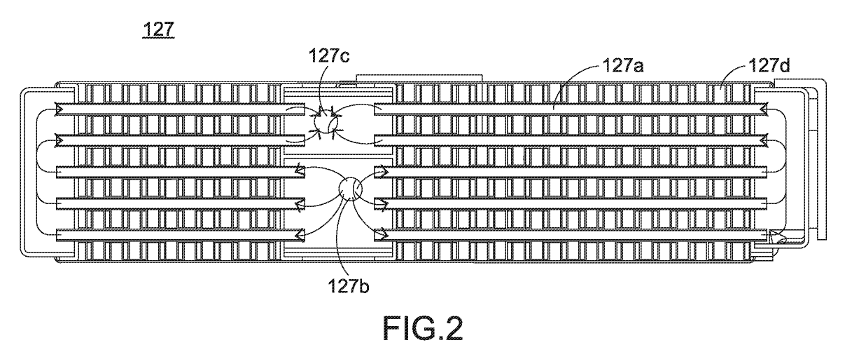

Please refer to FIGS. 1 and 2. FIG. 2 is a schematic cross-sectional view illustrating the first heat dissipation device of the dual-loop liquid cooling system according to the first embodiment of the present invention. In an embodiment, the first heat dissipation device 127 and the second heat dissipation device 137 are liquid cooling radiators. For succinctness, only the first heat dissipation device 127 of the first loop assembly 12 is shown in FIG. 2. The structure of the second heat dissipation device 137 of the second loop assembly 13 is similar to the structure of the first heat dissipation device 127 of the first loop assembly 12, and is not redundantly described herein. The liquid cooling radiator comprises a liquid cooling channel 127a, an entrance 127b, an exit 127c and plural fins 127d. The liquid cooling channel 127a, the entrance 127b and the exit 127c are in communication with each other. The plural fins 127d are in thermal contact with the liquid cooling channel 127a to absorb the heat of the working liquid and transfer and radiate the heat to the surroundings. After the first portion of the working liquid in the first loop assembly 12 is introduced into the liquid cooling channel 127a through the entrance 127b, the heat exchange between the working liquid and the first heat dissipation device 127 is performed. After the temperature of the working liquid is decreased, the working liquid is outputted from the liquid cooling channel 127a to the first liquid pump 126 through the exit 127c. Then, the working liquid with the decreased temperature is driven to the main liquid cooling head 11 by the first liquid pump 126. Then, the working liquid absorbs the heat of the main liquid cooling head 11 again.

The structure of the first pipe group 125 will be described as follows. In this embodiment, the first pipe group 125 comprises three first pipes 125a, 125c and 125d. The first pipe 125a is arranged between the main liquid cooling head 11 and the first heat dissipation device 127. The first pipe 125c is arranged between the first heat dissipation device 127 and the first liquid pump 126. The first pipe 125d is arranged between the first liquid pump 126 and the main liquid cooling head 11. The structure of the second pipe group 135 will be described as follows. Similarly, the second pipe group 135 comprises three second pipes 135a, 135c and 135d. The second pipe 135a is arranged between the main liquid cooling head 11 and the second heat dissipation device 137. The second pipe 135c is arranged between the second heat dissipation device 137 and the second liquid pump 136. The second pipe 135d is arranged between the second liquid pump 136 and the main liquid cooling head 11.

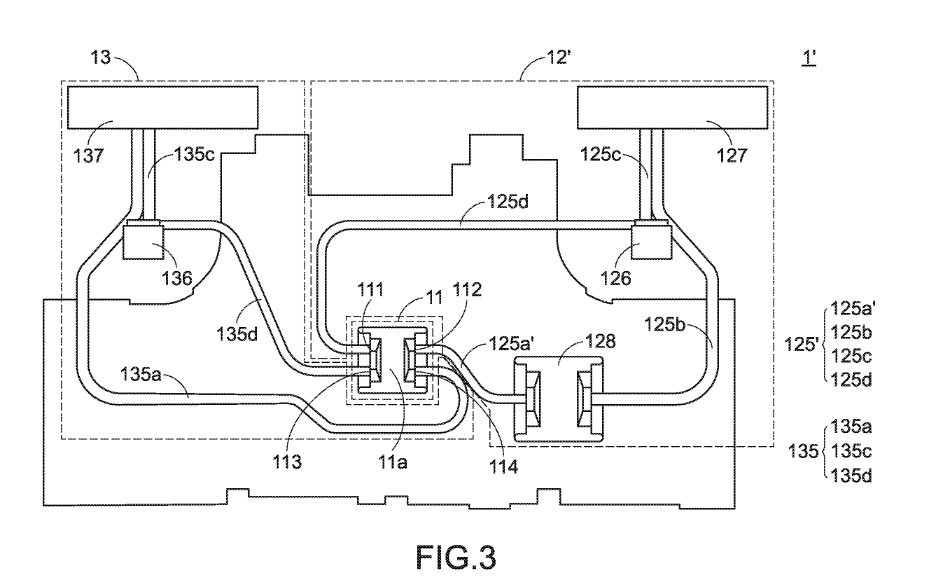

FIG. 3 is a schematic top view illustrating a dual-loop liquid cooling system according to a second embodiment of the present invention. In this embodiment, the dual-loop liquid cooling system 1′ comprises a main liquid cooling head 11, a first loop assembly 12′ and a second loop assembly 13. The structures of the main liquid cooling head 11 and the second loop assembly 13 of this embodiment are similar to those of the first embodiment. The first loop assembly 12′ and the second loop assembly 13 are individually in fluid communication with the main liquid cooling head 11 to dissipate the heat from the main liquid cooling head 11. The principles of dissipating the heat are similar to those mentioned above, and are not redundantly described herein. In this embodiment, the first loop assembly 12′ further comprises a first auxiliary liquid cooling head 128. The first auxiliary liquid cooling head 128 receives the first portion of the working liquid from the main liquid cooling head 11. After the first portion of the working liquid is transmitted through the first heat dissipation device 127 and the first liquid pump 126 sequentially, the first portion of the working liquid is returned back to the main liquid cooling head 11. Under this circumstance, a single loop assembly is able to remove the heat from two liquid cooling heads.

In this embodiment, the first pipe group 125′ comprises four first pipes 125a′, 125b, 125c and 125d. The first pipe 125a′ is arranged between the main liquid cooling head 11 and the first auxiliary liquid cooling head 128. The first pipe 125b is arranged between the first auxiliary liquid cooling head 128 and the first heat dissipation device 127. The first pipe 125c is arranged between the first heat dissipation device 127 and the first liquid pump 126. The first pipe 125d is arranged between the first liquid pump 126 and the main liquid cooling head 11.

It is noted that numerous modifications and alterations may be made while retaining the teachings of the invention. For example, in another embodiment, the second loop assembly 13 further comprises an auxiliary liquid cooling head. That is, the second loop assembly 13 further comprises a second auxiliary liquid cooling head (not shown). The second auxiliary liquid cooling head receives the second portion of the working liquid from the main liquid cooling head 11. After the second portion of the working liquid is transmitted through the second heat dissipation device 137 and the second liquid pump 136 sequentially, the first portion of the working liquid is returned back to the main liquid cooling head 11. The operations of the second loop assembly 13 are similar to those of the first loop assembly 12′, and are not redundantly described herein.

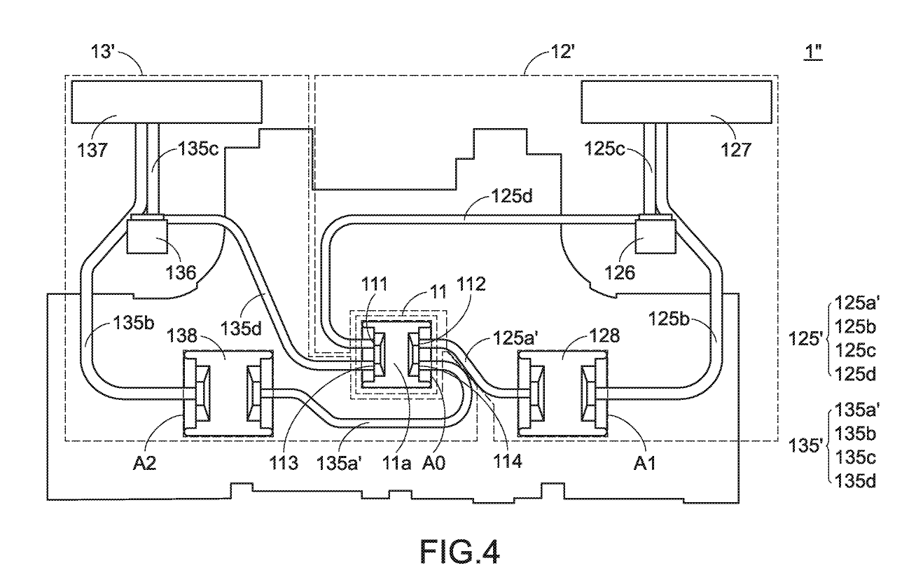

FIG. 4 is a schematic top view illustrating a dual-loop liquid cooling system according to a third embodiment of the present invention. In this embodiment, the dual-loop liquid cooling system 1″ comprises a main liquid cooling head 11, a first loop assembly 12′ and a second loop assembly 13′. The structure of the main liquid cooling head 11 of this embodiment is similar to that of the first embodiment. The first loop assembly 12′ and the second loop assembly 13′ are individually in fluid communication with the main liquid cooling head 11 to dissipate the heat from the main liquid cooling head 11. The principles of dissipating the heat are similar to those mentioned above, and are not redundantly described herein. In this embodiment, the first loop assembly 12′ further comprises a first auxiliary liquid cooling head 128, and the second loop assembly 13′ further comprises a second auxiliary liquid cooling head 138. After the first portion of the working liquid in the first loop assembly 12′ and the second portion of the working liquid in the second loop assembly 13′ are collected and mixed in the common chamber 11a of the main liquid cooling head 11, the working liquid is outputted from the first outlet 112 and the second outlet 114 and transmitted to the first auxiliary liquid cooling head 128 of the first loop assembly 12′ and the second auxiliary liquid cooling head 138 of the second loop assembly 13′. Consequently, the heat of other sites of the electronic device can be dissipated away. In this embodiment, the first pipe group 125′ comprises four first pipes 125a′, 125b, 125c and 125d, and the second pipe group 135′ comprises four second pipes 135a′, 135b, 135c and 135d.

In this embodiment, the main liquid cooling head 11 has a thermal contact area A0 for absorbing the heat from an external low-watt heat source. For example, the low-watt heat source is a computation unit of a main board. The first auxiliary liquid cooling head 128 and the second auxiliary liquid cooling head 138 have thermal contact areas A1 and A2 for absorbing the heat from two external high-watt heat sources. For example, the two external high-watt heat sources are two computation units of a display card. Moreover, the thermal contact areas A1 and A2 are larger than the thermal contact area A0. Consequently, the first auxiliary liquid cooling head 128 and the second auxiliary liquid cooling head 138 can absorb the heat of the high-watt heat sources more quickly.

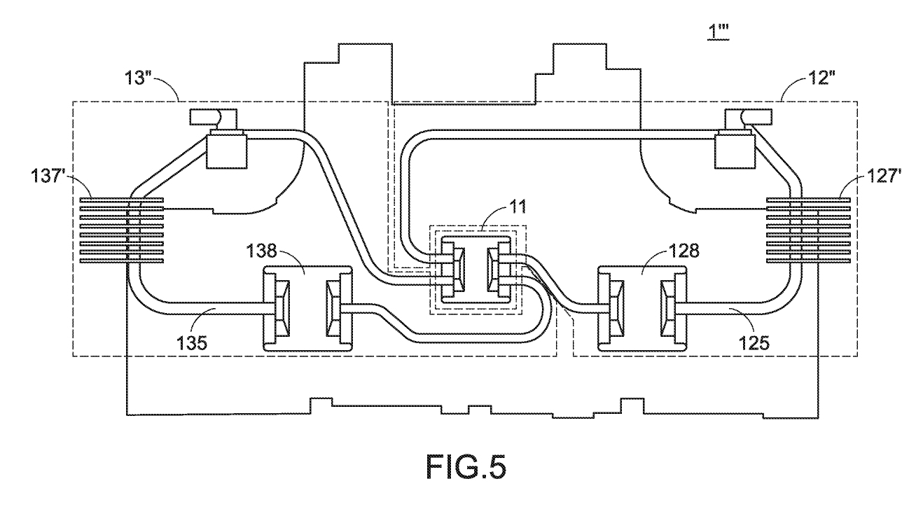

FIG. 5 is a schematic top view illustrating a dual-loop liquid cooling system according to a fourth embodiment of the present invention. In this embodiment, the dual-loop liquid cooling system 1′″ comprises a main liquid cooling head 11, a first loop assembly 12″ and a second loop assembly 13″. The structure of the main liquid cooling head 11 of this embodiment is similar to that of the first embodiment. The first loop assembly 12″ and the second loop assembly 13″ are individually in fluid communication with the main liquid cooling head 11 to dissipate the heat from the main liquid cooling head 11. The principles of dissipating the heat are similar to those mentioned above, and are not redundantly described herein. In comparison with the first embodiment, the first heat dissipation device 127′ and the second heat dissipation device 137′ of this embodiment include plural fins. These fins are directly installed on the first pipe group 125 and the second pipe group 135. Consequently, the heat of the working liquid in the first pipe group 125 and the second pipe group 135 can be dissipated away.

From the above descriptions, the present invention provides a dual-loop liquid cooling system. The dual-loop liquid cooling system includes two loop assemblies. The two loop assemblies are collaboratively connected with a main liquid cooling head in order to increase the efficiency of removing the heat from the main liquid cooling head. Since the dual-loop liquid cooling system includes the two loop assemblies, the volume of the single heat dissipation device can be reduced. Under this circumstance, the installation space is saved. Moreover, each loop assembly can remove heat from the main liquid cooling head and the auxiliary liquid cooling head sequentially. Consequently, the space utilization is enhanced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A dual-loop liquid cooling system, a working liquid flowing in the dual-loop liquid cooling system to facilitate heat dissipation, the dual-loop liquid cooling system comprising:
a main liquid cooling head comprising a common chamber, a first inlet, a first outlet, a second inlet and a second outlet, wherein the common chamber is in fluid communication with the first inlet, the first outlet, the second inlet and the second outlet;
a first loop assembly comprising a first pipe group, a first liquid pump and a first heat dissipation device, wherein two ends of the first pipe group are respectively connected with the first inlet and the first outlet of the main liquid cooling head, and the first pipe group is in fluid communication with the first liquid pump; and
a second loop assembly comprising a second pipe group, a second liquid pump and a second heat dissipation device, wherein two ends of the second pipe group are respectively connected with the second inlet and the second outlet of the main liquid cooling head, and the second pipe group is in fluid communication with the second liquid pump,
wherein a first portion of the working liquid in the first loop assembly is driven by the first liquid pump and introduced into the common chamber through the first inlet of the main liquid cooling head, and a second portion of the working liquid in the second loop assembly is driven by the second liquid pump and introduced into the common chamber through the second inlet of the main liquid cooling head, wherein after the first portion of the working liquid and the second portion of the working liquid are collected in the common chamber, the working liquid is returned back to the first loop assembly and the second loop assembly through the first outlet and the second outlet of the main liquid cooling head, respectively.

2. The dual-loop liquid cooling system according to claim 1, wherein the first loop assembly further comprises a first auxiliary liquid cooling head for receiving the first portion of the working liquid from the main liquid cooling head, and the first portion of the working liquid is sequentially transmitted through the first auxiliary liquid cooling head, the first heat dissipation device and the first liquid pump and returned back to the main liquid cooling head, and/or the second loop assembly further comprises a second auxiliary liquid cooling head for receiving the second portion of the working liquid from the main liquid cooling head, and the second portion of the working liquid is sequentially transmitted through the second auxiliary liquid cooling head, the second heat dissipation device and the second liquid pump and returned back to the main liquid cooling head.

3. The dual-loop liquid cooling system according to claim 2, wherein the main liquid cooling head has a thermal contact area for absorbing heat from an external low-watt heat source, and the first auxiliary liquid cooling head and the second auxiliary liquid cooling head have respective thermal contact areas for absorbing heat from two external high-watt heat sources, wherein the thermal contact area of the main liquid cooling head is smaller than the thermal contact area of the first auxiliary liquid cooling head and the thermal contact area of the second auxiliary liquid cooling head.

4. The dual-loop liquid cooling system according to claim 2, wherein the first pipe group comprises four first pipes, which are respectively arranged between the main liquid cooling head and the first auxiliary liquid cooling head, between the first auxiliary liquid cooling head and the first heat dissipation device, between the first heat dissipation device and the first liquid pump and between the first liquid pump and the main liquid cooling head, and/or the second pipe group comprises four second pipes, which are respectively arranged between the main liquid cooling head and the second auxiliary liquid cooling head, between the second auxiliary liquid cooling head and the second heat dissipation device, between the second heat dissipation device and the second liquid pump and between the second liquid pump and the main liquid cooling head.

5. The dual-loop liquid cooling system according to claim 1, wherein the first heat dissipation device and the second heat dissipation device are liquid cooling radiators, and each of the liquid cooling radiators comprises a liquid cooling channel, an entrance, an exit and plural fins, wherein the liquid cooling channel, the entrance and the exit are in communication with each other, and the plural fins are in thermal contact with the liquid cooling channel.

6. The dual-loop liquid cooling system according to claim 5, wherein after the first portion of the working liquid is introduced into the corresponding liquid cooling channel through the corresponding entrance to perform heat exchange, the first portion of the working liquid is outputted from the corresponding liquid cooling channel to the first liquid pump through the corresponding exit, and/or after the second portion of the working liquid is introduced into the corresponding liquid cooling channel through the corresponding entrance to perform heat exchange, the second portion of the working liquid is outputted from the corresponding liquid cooling channel to the second liquid pump through the corresponding exit.
